(19) United States
(12) Patent Application Publication
(10) Pub. No.: US 2018/0310392 A1
(43) Pub. Date: Oct. 25, 2018

(54) ANTI-ELECTROSTATIC WRIST STRAP AND GROUND DETECTION DEVICE

(71) Applicant: HSIN-MING YANG, Taipei City (TW)

(72) Inventor: HSIN-MING YANG, Taipei City (TW)

(21) Appl. No.: 15/956,807

(22) Filed: Apr. 19, 2018

(30) Foreign Application Priority Data
Apr. 21, 2017 (TW) 106113531

(51) Int. Cl. H05F 3/02; G01R 27/20

(52) U.S. Cl. CPC H05F 3/02; G01R 27/20

(57) ABSTRACT

An anti-electrostatic wrist strap and a ground detection device are provided so as to prevent misjudgment resulted from a wrist strap wearer's skin being too dry. The wrist strap includes a resistor having resistance R connected between the wrist strap's two wires. Therefore a tolerance range is created when monitoring whether the wrist strip has an appropriate resistance. Similarly, the detection device includes a resistor having resistance R parallel-connected to its detection circuit to a wrist strap. A tolerance range is created when monitoring whether the wrist strip has an appropriate resistance. By the wrist strap or the detection device, the chance of misjudgment is effectively reduced. To further enhance electrostatic protection, the detection device includes a power provision interface and an electrical switch so that, only when the electrostatic leakage circuit has an appropriate resistance, the electrical switch enables the power provision interface to supply electricity to related apparatuses.

### CROSS-REFERENCE TO RELATED APPLICATION

This application claims the priority of Taiwanese patent application No. 106113531, filed on Apr. 21, 2017, which is incorporated herewith by reference.

### BACKGROUND OF THE INVENTION

### 1. Field of the Invention

The present invention generally relates to an anti-electrostatic wrist strap and a ground detection device, and more specifically to an anti-electrostatic wrist strap preventing misjudgment resulted from a wrist strap wearer's skin being too dry, and a ground detection device.

### 2. The Prior Arts

As the electronic products need to be much lighter, thinner, shorter, and smaller, and the electronic elements become more precise, electrostatic protection in the production process has been more important.

In general, a mass production line includes a plurality of work tables for processing or assembly. To prevent instruments, machines, and tools on the work tables from electrostatic damage during manufacturing the products, each operator working by the work table is required to wind an anti-electrostatic wrist strap around one wrist. Particularly, a floor mat and a table mat for anti-electrostatic protection are provided on the floor and the work table, respectively. As shown in FIG. 1a, a floor mat 10, a table mat 20, and a wrist strap 30 are usually connected to a common point ground 40 through a cable to form an anti-electrostatic leakage loop. The common point ground 40 is a metal sheet or wire, which is fixed to the work table, and covered with an insulation shell for isolation and protection. For simplicity, only the connection between the common point ground 40 and the wrist strap 30 is depicted. All of the common point grounds 40 of the work tables of one production line are often connected in series or parallel, and then to an equipment ground or earth ground (not shown).

The operator sometimes needs to temporarily leave the work table (for example, go to toilet or have lunch), and the wrist strap 30 is disconnected from the common point ground 40 or put down from the wrist. When the operator returns, the wrist strap 30 is re-connected to the common point ground 40 or worn on the wrist again. In the prior arts, Taiwan Patent No. I349778 and No. I368746 disclosed a wireless ground detection device, which employs and senses wireless power transfer. If the operator is assured to work by the work table, the wireless ground detection device further detects resistance of the leakage loop built in the anti-electrostatic wrist strap to determine if the operator connects the wrist strap 30 to the common point ground 40, or puts on the wrist strap 30.

The wireless ground detection device 100 in the above patent is further simplified as shown in FIG. 1b. Specifically, the wireless ground detection device 100 is connected to the city power through a power cable or an external power supply like the notebook computer to acquire power for the power supply and processing circuit 300 as well as the ground 60 from the city power (only the ground 60 is depicted for simplicity). The wireless ground detection device 100 is also connected to the equipment or earth ground (just called the earth ground hereinafter) 50 (implemented by the above common point ground 40). The wireless ground detection device 100 is connected to two conductive wires 31 and 32 of the anti-electrostatic wrist strap 30 through an anti-electrostatic wrist strap interface 110. As shown in FIG. 1c, two ends of the conductive wires 31 and 32 are connected to two conductive sheets 33 built in the anti-electrostatic wrist strap 30, respectively. The anti-electrostatic wrist strap 30 generally has an insulation strap with an elastic band or buckle, and the conductive sheets 33 are on the outer surface of the insulation strap to be in contact with the operator's skin.

Another end of the conductive wire 31 is connected to the earth ground 50 through the wireless ground detection device 100, and another end of the conductive wire 32 is connected to the city power ground 60 through the power supply and processing circuit 300. Thus, when the operator wears the anti-electrostatic wrist strap 30, a leakage loop is formed by the city power ground 60, the earth ground 50, the conductive wire 31, the operators skin 70, the conductive wire 32, and the power supply and processing circuit 300 as shown in FIG. 1b. One of the key features of the power supply and processing circuit 300 is detect resistance of the leakage loop and determine if resistance of the leakage loop is within a preset range (or issue a warning). Based on the regulation of electrostatic protection defined by ANSI/ESD S20.20-2014, the leakage loop in the anti-electrostatic wrist strap 30 should have resistance less than 35 MΩ.

The above scheme in the prior arts is indeed effective for the mass production line. However, even when the operator correctly wears the anti-electrostatic wrist strap 30, resistance of the leakage loop is still possibly too high due to the operator's skin too dry, causing the ground detection device to perform a misjudgment process. In addition, the effect of protection by just issuing the warning is not sufficient, and further improvement for the electrostatic protection has been a crucial topic for the related manufacturers.

### SUMMARY OF THE INVENTION

The primary objective of the present invention is to provide an anti-electrostatic wrist strap and a ground detection device, increasing stability of detection and preventing misjudgment resulted from a wrist strap wearer's skin being too dry.

The key feature of the present invention is that the principle of parallel-connection circuit is skillfully utilized to create a tolerable range.

The anti-electrostatic wrist strap of the present invention provides a resistor with resistance R between two conductive wires. For the traditional detection scheme, resistance of the operator's skin has to be less than a threshold T. However, with the anti-electrostatic wrist strap of the present invention provided with the resistor, resistance of the operator's skin is only required to be less than (T·R)/(R−T), and also less than the threshold T after being connected to the resistor in parallel. In other words, the anti-electrostatic wrist strap of the present invention creates the tolerable range from T to (T·R)/(R−T), thereby greatly and effectively decreasing the chances of misjudgment. As a result, the stability of detection is improved. The anti-electrostatic wrist strap of the present invention should be collocated with the traditional ground detection device.

The ground detection device of the present invention employs a resistor with resistance R to parallel-connect to the detection loop of the anti-electrostatic wrist strap, and thus creates the above tolerable range to effectively reduce the chances of misjudgment. As a result, the stability of detection is improved. The ground detection device of the present invention should be collocated with the traditional anti-electrostatic wrist strap.

To further enhance electrostatic protection, the ground detection device of the present invention comprises a power supply interface and a power control switch. The power supply interface is intended to connect the related electrical devices on the work table and supply power for operation. Only when the leakage loop is detected to have an appropriate value of resistance, the power control switch triggers the power supply interface to supply power to the related apparatuses on the work table. In other words, when the ground detection device detects an abnormal value of resistance in the leakage loop, the related apparatuses on the work table fail to operate because of no power, thereby avoiding electrostatic damage.

### BRIEF DESCRIPTION OF THE DRAWINGS

The present invention can be understood in more detail by reading the subsequent detailed description in conjunction with the examples and references made to the accompanying drawings, wherein:

FIG. 1a is a view showing the ground architecture of the work table in the prior arts;

FIG. 1b is a functional block diagram of the anti-electrostatic wrist strap and a ground detection device in the prior arts;

FIG. 1c is a view showing the anti-electrostatic wrist strap in the prior arts;

FIG. 2a is a view showing the anti-electrostatic wrist strap according to the present invention;

FIG. 2b is a view showing the equivalent circuit of the anti-electrostatic wrist strap shown in FIG. 2a;

FIG. 3a is a view showing the ground detection device according to the first embodiment of the present invention;

FIG. 3b is a view showing the ground detection device according to the second embodiment of the present invention; and

FIG. 3c is a view showing the ground detection device according to the third embodiment of the present invention.

### DETAILED DESCRIPTION OF THE PREFERRED EMBODIMENT

The present invention may be embodied in various forms and the details of the preferred embodiments of the present invention will be described in the subsequent content with reference to the accompanying drawings. The drawings (not to scale) show and depict only the preferred embodiments of the invention and shall not be considered as limitations to the scope of the present invention. Modifications of the shape of the present invention shall too be considered to be within the spirit of the present invention.

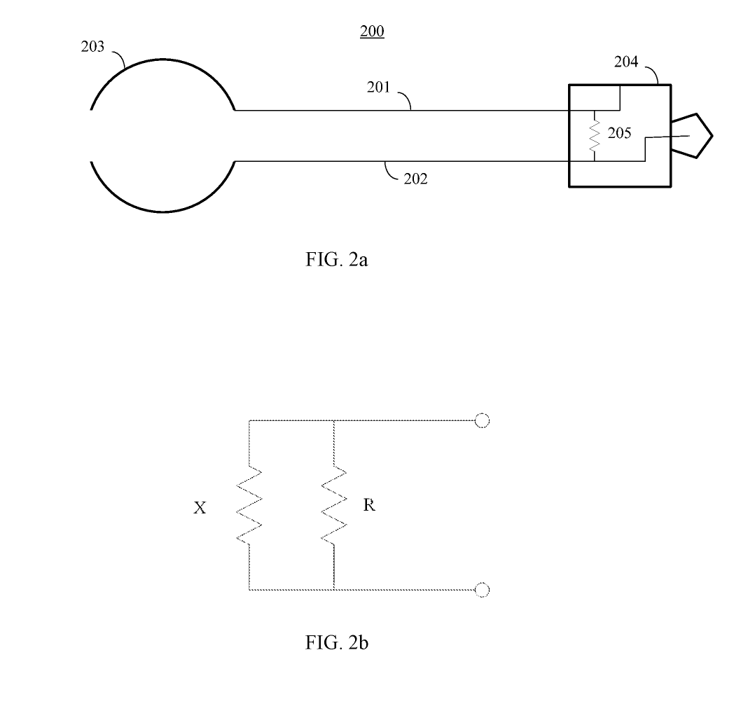

Please refer to FIG. 2a illustrating the anti-electrostatic wrist strap according to the present invention. As shown in FIG. 2a, the anti-electrostatic wrist strap 200 comprises two conductive wires 201 and 202, two conductive sheets 203 respectively connected to the two conductive wires 201 and 202, and a connector 204. The two conductive sheets 203 are generally provided on an inner side of an outer insulation strap (not shown). An operator winds the outer insulation strap around the wrist, and uses an elastic band or buckle to make the two conductive sheets 203 in contact the skin of the operator's wrist. The two conductive wires 201 and 202 are coated with an insulation sleeve (not shown). The two conductive wires 201 and 202 and the two conductive sheets 203 are fixed together or detachably joint by means of button. The connector 204 is connected to a ground detection device to form a leakage loop. In one embodiment of the present invention, the connector 204 is a so-called TS (tip and sleeve) connector, which is commonly used in the audio device. Thus, the conductive wires 201 is connected to the sleeve part of the connector 204, and the conductive wires 202 is connected to the tip part of the connector 204. In other words, the first ends of the conductive wires 201 and 202 are respectively in contact with two different points on the wearer's skin, and the second ends of the conductive wires 201 and 202 are connected to the ground detection device. Generally, two resistors of 800K-1.2 MΩ are connected to the conductive wires 201 and 202, respectively. For simplicity, the two resistors are not shown in FIG. 2a, and thus omitted in the following description. The above anti-electrostatic wrist strap in the prior arts is common, and detailed description is also omitted.

The anti-electrostatic wrist strap 200 further comprises a resistor 205 between the conductive wires 201 and 202. As shown in FIG. 2a, the resistor 205 is provided in the connector 204 in the embodiment of the present invention. However, it is not intended to limit the scope of the present invention, and the resistor 205 can be provided between the conductive wires 201 and 202, or between the two conductive sheets 203 and the connector 204.

FIG. 2b is a view showing the equivalent circuit of the anti-electrostatic wrist strap of the present invention. Resistance R represents resistance of the resistor 205, and resistance X is resistance between the two conductive sheets 203. According to a formula for two parallel-connected resistors, the equivalent resistance of the anti-electrostatic wrist strap 200 (that is, resistance from the two contact points of the connector 204) is X·R/(X+R). When the operator does not wear the anti-electrostatic wrist strap 200, resistance X between the two conductive sheets 203 approximates to infinity, and the equivalent resistance of the anti-electrostatic wrist strap 200 is thus R. When the two conductive sheets 203 are shorted, resistance X between the two conductive sheets 203 is approximately zero, and the equivalent resistance of the anti-electrostatic wrist strap 200 is also approximately zero. Therefore, when the operator wears the anti-electrostatic wrist strap 200, the equivalent resistance of the anti-electrostatic wrist strap 200 is within 0 and R.

According to anti-electrostatic regulation defined by ANSI/ESD S20.20-2014, resistance for correctly wearing the anti-electrostatic wrist strap should be less than 35 MΩ. Thus, the ground detection device in the prior arts generally takes 35 MΩ as a threshold. When the anti-electrostatic wrist strap 200 is detected to have resistance exceeding 35 MΩ, it is recognized that the anti-electrostatic wrist strap 200 is not put on and an alarm is issued. However, when resistance X between the two conductive sheets 203 becomes higher because of the operator's skin too dry or other reasons, misjudgment could happen. If the resistor 205 of the present invention like 50 MΩ is provided, and even when resistance X between the two conductive sheets 203 increases up to 100 MΩ as a result of the operator's skin too dry, the equivalent resistance of the anti-electrostatic wrist strap 200 is just (100.50)/(100+50)=33.33 MΩ, which is still below the threshold 35 MΩ. Thus, misjudgment is prevented.

In case T represents the threshold, the traditional regulation requires resistance of the operator's skin is less than T (that is, XT), but with the resistor 205, resistance X of the operator's skin just needs to be less than T·R/(R−T) (that is, X≤(T·R)/(R−T)), which is deducted from (X·R)/(X+R)≤T, in order to meet the threshold T. In other words, a tolerable range of T to (X·R)/(X+R)≤T is created by use of the resistor 205. Accordingly, for the case of T=35 MΩ and R=50 MΩ, resistance of the operator's skin should be less than 35 MΩ by the traditional regulation. After the resistor 205 is provided, however, resistance X of the operator's skin is allowed to be less than (35.50)/(50−35)≈117 MΩ. A tolerable range of 35 MΩ to 117 MΩ is thus created.

Therefore, with an appropriate value of resistance R, the anti-electrostatic wrist strap of the present invention can avoid misjudgment due to the operator's skin too dry. To meet the threshold required by the regulation, resistance R should be larger than or equal to 35 MΩ. In one embodiment, resistance R is implemented between 35 MΩ and 100 MΩ. In another embodiment, resistance R is 50 MΩ.

As above-mentioned, the anti-electrostatic wrist strap of the present invention utilized the traditional circuit scheme of parallel connection to create the tolerable range for the operator's skin too dry. Particularly, the present invention can be fully collocated with the traditional ground detection device without any modification.

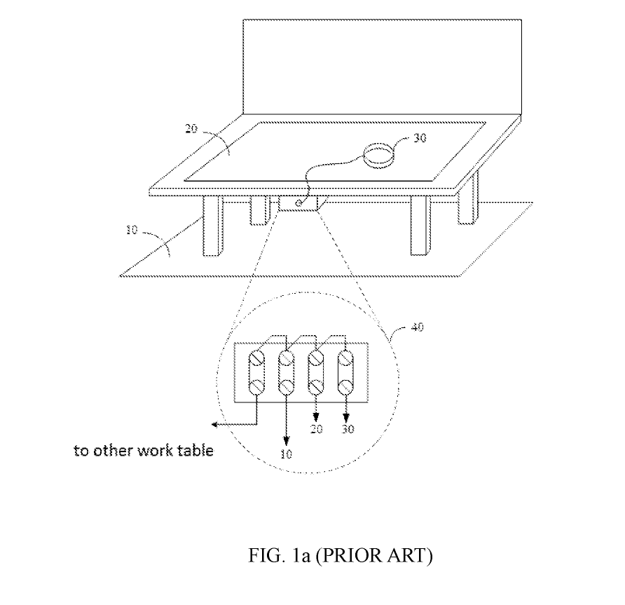

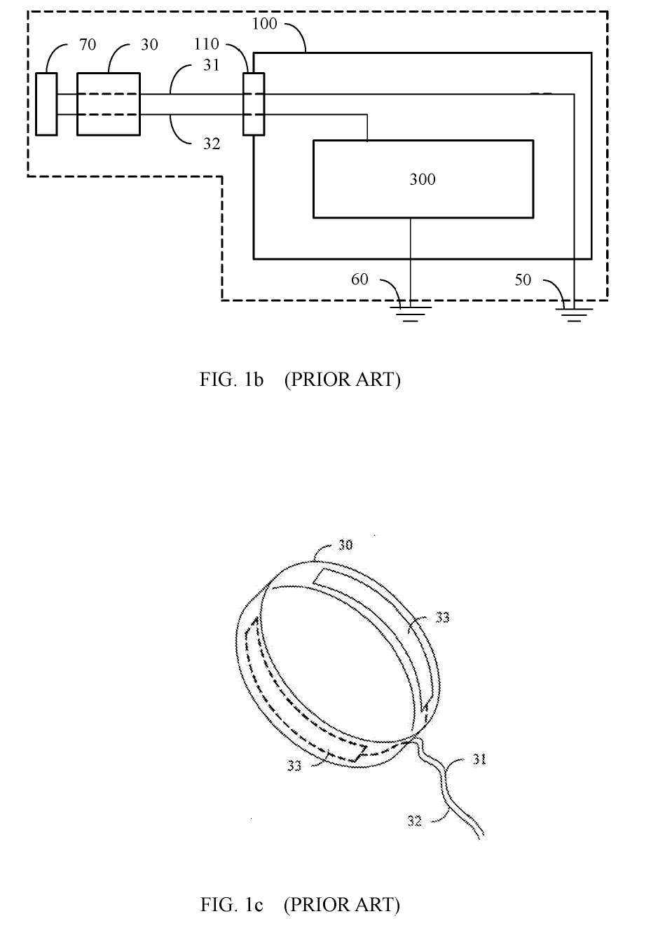

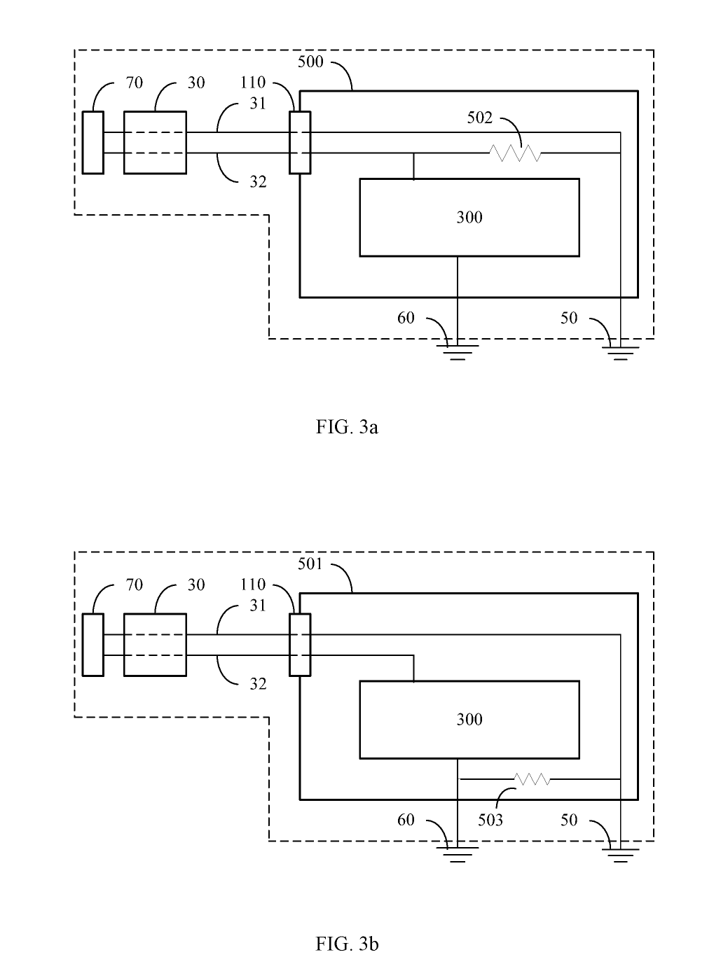

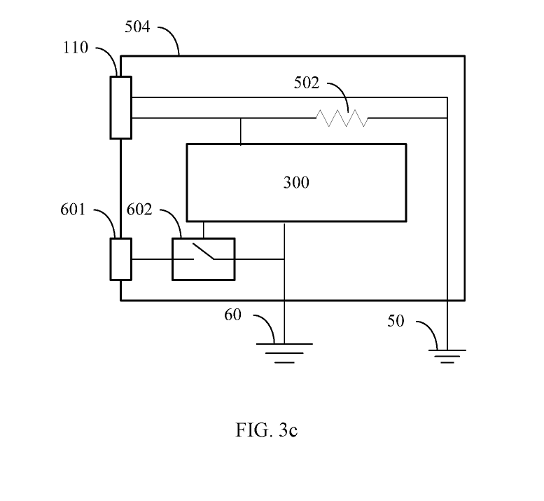

With reference to FIGS. 3a and 3b illustrating the ground detection devices 500 and 501 according to the first and second embodiments of the present invention, respectively. Each of the ground detection devices 500 and 501 is collocated with and connected to a traditional anti-electrostatic wrist strap through an anti-electrostatic wrist strap interface 110. By comparison with the ground detection device shown in FIG. 1b, the difference between the ground detection devices 500 and 501 of the present invention and the ground detection devices in the prior arts is just that the resistors 502 and 503 are parallel-connected to the electrostatic leakage loops (represented by a dashed line) of the present invention, respectively. The detailed description of the elements of the ground detection devices 500 and 501 according to the present invention which have the same numerals as the traditional ground detection device 100 is omitted for simplicity.

As shown in FIG. 3a, the resistor 502 is parallel-connected to the electrostatic leakage loop built in the ground detection device 500, and specifically provided between the anti-electrostatic wrist strap interface 110 and the power supply and processing circuit 300. In another embodiment (not shown), the resistor 502 is provided on the anti-electrostatic wrist strap interface 110 and between the two conductive wires 31 and 32 of the anti-electrostatic wrist strap 30.

As shown in FIG. 3b, the resistor 503 is parallel-connected to the electrostatic leakage loop built in the ground detection device 501, and specifically provided between the power supply and processing circuit 300 and the ground 50 and 60.

It should be noted that the resistors 502 and 503 are not limited to the above configurations. As the previously mentioned, any configuration that the resistors 502 and 503 are built in the ground detection device 500, and parallel-connected to the electrostatic leakage loop is included. One of the advantages provided by the two embodiments is that the ground detection devices 501 and 502 are easily implemented by simply modifying the traditional ground detection device 100, and the power supply and processing circuit 300 remains without any hardware change.

According to the embodiments as shown in FIGS. 3a and 3b, the equivalent circuit of the electrostatic leakage loop seen from the power supply and processing circuit 300 is illustrated by FIG. 2b, wherein resistance R represents the value of resistance of the resistors 502 and 503, and resistance X is the value of equivalent resistance of the anti-electrostatic wrist strap 30. Thus, if T represents the threshold of detection, the condition required by the regulation is met as long as resistance X of the operator' skin is less than (T·R)/(R−T), thereby creating the tolerable range of T to (T·R)/(R−T).

The traditional ground detection device 100 just provides a warning function due to possible misjudgment. However, the anti-electrostatic wrist strap and the ground detection device of the present invention effectively reduce chances of misjudgment and further provide a function of active anti-electrostatic protection. FIG. 3c is a view showing the ground detection device 504 according to the third embodiment of the present invention. As shown in FIG. 3c, the ground detection device 504 is modified from the first embodiment, and the detailed description of the elements with the same numerals is omitted hereinafter.

The ground detection device 504 further comprises at least one power supply interface 601 and a power control switch 602. In the present embodiment, the power supply interface 601 is a power socket for connecting the power cable to supply power for the related electrical devices provided on the work table. As mentioned before, the power supply interface 601 is connected to the city power through the power cable or the external power supply (not shown). In addition to the power for the power supply and processing circuit 300, the ground 60 of the city power is also acquired. Each power supply interface 601 is connected to the power cable or the external power supply to obtain the city power. The power control switch 602 can be implemented by an electronic rely or a TRIAC (triode for alternating current), which is connected in series between the power supply interface 601 and the city power. The power control switch 602 is further connected to the power supply and processing circuit 300 and driven by the related electrical signal like a trigger warning or a turn-off warning from the power supply and processing circuit 300. The scheme of the related signal is well known to those skilled in this field, and the detailed description is thus omitted hereinafter.

For instance, the power control switch 602 can be a normal close switch. When the power supply and processing circuit 300 detects an abnormal value of resistance in the electrostatic leakage loop like larger than 35 MΩ, some sound, optical or message warning is triggered, and the triggered signal is also intended to drive the power control switch 602 to disconnect the power supply interface 601 and the city power. The related work table is thus prevented from electrostatic damage because of stopping normal operation. When the power supply and processing circuit 300 detects that resistance in the electrostatic leakage loop recovers to a normal value like less than 35 MΩ, the sound, optical or message warning is first ceased, and the turn-off signal is then used to drive the power control switch 602 to recover the connection between the power supply interface 601 and the city power. Thus, normal operation of the work table is allowed to continue and perform.

The ground detection device 504 of the present embodiment is collocated with the traditional anti-electrostatic wrist strap. For another embodiment of the present invention, he traditional anti-electrostatic wrist strap 100 is combined with the above-mentioned power supply interface 601 and the power control switch 602 (that is, the case of the ground detection device 504 omitting the resistor 502). The ground detection device needs to be collocated with the anti-electrostatic wrist strap, but the principle of operation is substantially the same

Although the present invention has been described with reference to the preferred embodiments, it will be understood that the invention is not limited to the details described thereof. Various substitutions and modifications have been suggested in the foregoing description, and others will occur to those of ordinary skill in the art. Therefore, all such substitutions and modifications are intended to be embraced within the scope of the invention as defined in the appended claims.

What is claimed is:

1. An anti-electrostatic wrist strap, comprising two conductive wires and a connector, one end of each of the two conductive wires in contact with one specific point on a wearer's skin, another end of each of the two conductive wires connected to the connector, the anti-electrostatic wrist strap characterized by:
the anti-electrostatic wrist strap further comprising a resistor, two ends of the resistor connected to the two conductive wires and in contact with the two points on the wearer's skin.

2. The anti-electrostatic wrist strap as claimed in claim 1, wherein the resistor is provided in the connector.

3. The anti-electrostatic wrist strap as claimed in claim 1, wherein the resistor has resistance larger than or equal to 35 MΩ.

4. A ground detection device connected to an anti-electrostatic wrist strap and a ground, provided between the anti-electrostatic wrist strap and a ground to form an electrostatic leakage loop, comprising an anti-electrostatic wrist strap interface and a power supply and processing circuit, the anti-electrostatic wrist strap connected to a connector, the power supply and processing circuit connected to the electrostatic leakage loop in series to detect resistance of the electrostatic leakage loop, the ground detection device characterized by:
the ground detection device further comprising a resistor provided in ground detection device and connected to the electrostatic leakage loop in parallel.

5. The ground detection device as claimed in claim 4, wherein the resistor is provided between the anti-electrostatic wrist strap interface and the power supply and processing circuit.

6. The ground detection device as claimed in claim 5, wherein the resistor is provided on the anti-electrostatic wrist strap.

7. The ground detection device as claimed in claim 4, wherein the resistor is provided between the power supply and processing circuit and the ground.

8. The ground detection device as claimed in claim 4, wherein the resistor has resistance larger than or equal to 35 MΩ.

9. The ground detection device as claimed in claim 8, wherein the resistor has resistance less than or equal to 100 MΩ.

10. The ground detection device as claimed in claim 4, further comprising a power supply interface and a power control switch, the power supply interface connected to a city power to supply power to related electrical devices, the power control switch connected to the power supply interface and the city power, the power control switch further connected to the power supply and processing circuit to be driven by a related electrical signal for a triggering warning or a turn-off warning issued by the power supply and processing circuit to conduct or turn off a connection of the power supply interface and the city power.

11. A ground detection device in collocation with the anti-electrostatic wrist strap as claimed in claim 1, provided between the anti-electrostatic wrist strap and a ground to form an electrostatic leakage loop, comprising an anti-electrostatic wrist strap interface and a power supply and processing circuit, the anti-electrostatic wrist strap connected to a connector, the power supply and processing circuit connected to the electrostatic leakage loop in series to detect resistance of the electrostatic leakage loop, the ground detection device characterized by:
the ground detection device further comprising a power supply interface and a power control switch, the power supply interface connected to a city power to supply power to related electrical devices, the power control switch connected to the power supply interface and the city power, the power control switch further connected to the power supply and processing circuit to be driven by a related electrical signal for a triggering warning or a turn-off warning issued by the power supply and processing circuit to conduct or turn off a connection of the power supply interface and the city power.
